(19) United States
(12) Patent Application Publication
(10) Pub. No.: US 2026/0093288 A1
(43) Pub. Date: Apr. 2, 2026

(54) DISPLAY DEVICE

(71) Applicant: LG Display Co., Ltd., Seoul (KR)

(72) Inventor: Sungjin PARK, Seoul (KR)

(73) Assignee: LG Display Co., Ltd., Seoul (KR)

(21) Appl. No.: 19/314,283

(22) Filed: Aug. 29, 2025

(30) Foreign Application Priority Data
Sep. 27, 2024 (KR) 10-2024-0131865

(51) Int. Cl. G06F 1/16; H05K 1/02

(52) U.S. Cl. CPC G06F 1/1656; G06F 1/1652; H05K 1/0281

(57) ABSTRACT

Provided is a display device. The display device includes an active area and a non-active area including a first non-active area adjacent to the active area, a bending area extending from the first non-active area, and a second non-active area extending from one side of the bending area. The display device comprises a first glass substrate disposed in the active area; a second glass substrate disposed in the second non-active area; an etch stop layer which is disposed so as to overlap the bending area; a link line disposed on the etch stop layer across the bending area; a micro coating layer which is disposed so as to overlap the first non-active area and at least a part of the second non-active area and is disposed on the link line in the bending area; and a rigid member which is disposed on the micro coating layer to be adjacent to the bending area so as to overlap at least a part of the second glass substrate.

### CROSS-REFERENCE TO RELATED APPLICATIONS

This application claims the priority of Korean Patent Application No. 10-2024-0131865 filed on Sep. 27, 2024, in the Korean Intellectual Property Office, the disclosure of which is incorporated herein by reference.

### BACKGROUND

### Technical Field

The present disclosure relates to a display device, and more particularly, to a display device which reduces a stress while bending a bezel.

### Description of the Related Art

Generally, display devices are widely used as display screens for various electronic devices, such as mobile communication terminals, electronic notebooks, electronic books, portable multimedia players (PMPs), navigation, ultra-mobile PCs (UMPC), mobile phones, smart phones, tablet PCs (Personal Computers), watch phones, electronic pads, wearable devices, portable information devices, vehicle control display devices, televisions, laptops, and monitors.

Recently, display devices which implement a maximum screen by reducing a bezel area in which images are not displayed with the same size of the display panel are being studied and developed.

### BRIEF SUMMARY

An object to be achieved by the present disclosure is to provide a display device which is capable of minimizing a width of a bezel area.

Another object to be achieved by the present disclosure is to provide a display device which reduces a deformation of a micro coating layer while bending a bezel.

Still another object to be achieved by the present disclosure is to provide a display device which reduces a stress generated in a bending area and improves reliability.

Objects of the present disclosure are not limited to the above-mentioned objects, and other objects, which are not mentioned above, can be clearly understood by those skilled in the art from the following descriptions.

According to an aspect of the present disclosure, a display device which includes an active area and a non-active area including a first non-active area adjacent to the active area, a bending area extending from the first non-active area, and a second non-active area extending from one side of the bending area includes a first glass substrate disposed in the active area, a second glass substrate disposed in the second non-active area, an etch stop layer which is disposed so as to overlap the bending area, a link line disposed on the etch stop layer across the bending area, a micro coating layer disposed on the link line in the bending area, and a rigid member which is disposed on the micro coating layer so as to overlap at least a part of the second glass substrate to be adjacent to the bending area.

Other detailed matters of the exemplary embodiments are included in the detailed description and the drawings.

According to the present disclosure, when a bezel is bent, a deformation of a micro coating layer in a bending area is suppressed to reduce a stress due to the bending.

According to the present disclosure, a rigid member is disposed on the micro coating layer to reduce a stress of a link line in a bending area.

According to the present disclosure, a stress generated due to expansion and contraction generated in a high temperature and low temperature environment in the bending area is alleviated to improve the reliability.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure;

FIG. 2 is a cross-sectional view of an active area of a display device according to an exemplary embodiment of the present disclosure;

FIG. 3A is a cross-sectional view of a state before being bent taken along A-A′ of FIG. 1;

FIG. 3B is a cross-sectional view of a state after being bent taken along A-A′ of FIG. 1;

FIG. 4 is a cross-sectional view of a display device according to another exemplary embodiment of the present disclosure;

FIGS. 5A and 5B are cross-sectional views of a display device according to still another exemplary embodiment of the present disclosure;

FIGS. 6A and 6B are cross-sectional views of a display device according to still another exemplary embodiment of the present disclosure;

FIGS. 7A and 7B are plan views of a display device according to another exemplary embodiment of the present disclosure;

FIGS. 8A and 8B are simulation results for a stress of a display device according to a comparative embodiment;

FIGS. 9A and 9B are simulation results for a stress of a display device according to an exemplary embodiment of the present disclosure; and

FIG. 10 is a graph obtained by analyzing a stress of a link line in a bending area according to a modulus of a rigid member according to an exemplary embodiment of the present disclosure by a finite element method.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

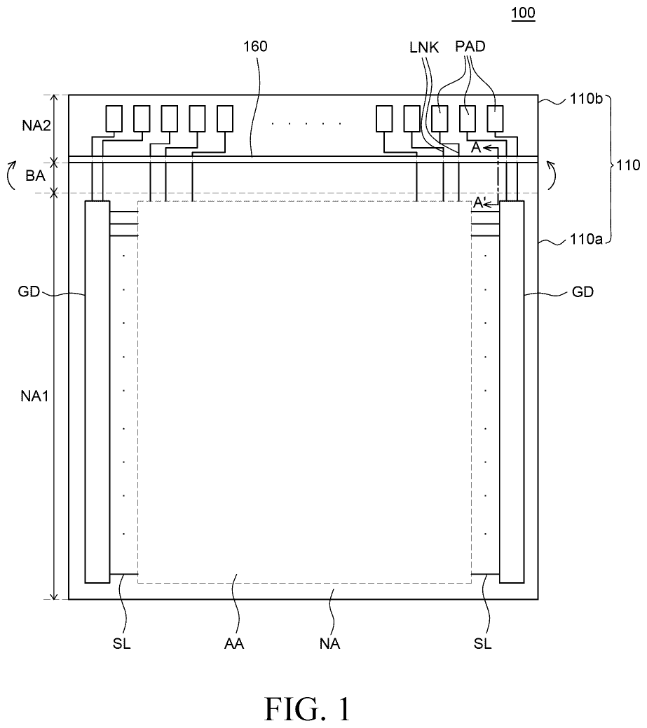

FIG. 1 is a plan view of a display device according to an exemplary embodiment of the present disclosure.

Referring to FIG. 1, a glass substrate 110 of the display device 100 according to the exemplary embodiment of the present disclosure includes an active area AA and a non-active area NA which encloses an outer periphery of the active area AA. In the active area, a sub pixel which actually emits light through a thin film transistor and a light emitting diode is disposed.

The active area AA may be an area where a plurality of sub pixels is disposed to display images. Each of the plurality of sub pixels is an individual unit which emits light and in each of the plurality of sub pixels PX, a light emitting diode and a driving circuit may be formed. For example, in the plurality of sub pixels, the display elements for displaying images and circuit units for driving the display elements may be disposed. At this time, when the display device 100 is an organic light emitting display device, the display element may include an organic light emitting diode and when the display device 100 is a liquid crystal display device, the display element may include a liquid crystal element. The plurality of sub pixels may include a red sub pixel, a green sub pixel, a blue sub pixel, and a white sub pixel, but is not limited thereto. The driving circuit may include various thin film transistors, storage capacitors, and wiring lines for driving the plurality of sub pixels. For example, the driving circuit may be configured by various components, such as a driving thin film transistor, a switching thin film transistor, a sensing thin film transistor, a storage capacitor, a gate line, and a data line, but is not limited thereto.

In the non-active area NA, a circuit, such as a gate driver GD for driving a display device 100 and various signal lines, such as a scan line SL which is a gate line may be disposed. Further, the gate driver GD for driving the display device 100 may be disposed on the glass substrate 110 in a gate in panel (GIP) manner or connected to the glass substrate 110 in a tape carrier package (TCP) or a chip on film (COF) manner.

The non-active area NA may include a first non-active area NA1 adjacent to the active area AA, a bending area BA extending from the first non-active area NA1, and a second non-active area NA2 extending from one side of the bending area BA.

Specifically, the first non-active area NA1 is an area in which an image is not displayed and is disposed so as to enclose the active area AA. In the first non-active area NA1, various wiring lines and driving ICs for driving a plurality of sub pixels disposed in the active area AA may be disposed. The first non-active area NA1 in which an image is not displayed may be a bezel area and exemplary embodiments of the present disclosure are not limited thereto.

A part of the non-active area NA may be bent in a bending direction illustrated by an arrow in FIG. 1. An area which is bent as described above may be referred to as a bending area BA. In other words, the bending area BA is a part of the first non-active area NA1 which extends from one side of the non-active area NA and may be an area to be bent.

In the second non-active area NA2 extending from one side of the bending area BA, a pad unit PAD is disposed. The pad unit PAD may include a plurality of pad electrodes to which an external module is bonded.

Various wiring lines are formed on the glass substrate 110. The wiring line may be disposed in the active area AA of the glass substrate 110 and may also be disposed in the non-active area NA. Specifically, a link line LNK formed in the non-active area NA is connected to a driving circuit, for example, a gate driver GD or a data driver to transmit a signal.

The link line LNK is formed of a conductive material and may be formed of a conductive material having an excellent ductility to reduce the crack generated at the time of bending the glass substrate 110. For example, the link line LNK may be formed of a conductive material having excellent ductility such as gold (Au), silver (Ag), and aluminum (Al) and formed of one of various conductive materials used in the active area AA. The link line LNK may also be configured by molybdenum (Mo), chrome (Cr), titanium (Ti), nickel (Ni), neodymium (Nd), copper (Cu), and an alloy of silver (Ag), and magnesium (Mg). Further, the link line LNK may be configured by a multi-layered structure including various conductive materials and for example, configured by a triple layered structure of titanium (Ti)/aluminum (Al)/titanium (Ti), but the structure of the link line LNK according to the present disclosure is not limited thereto.

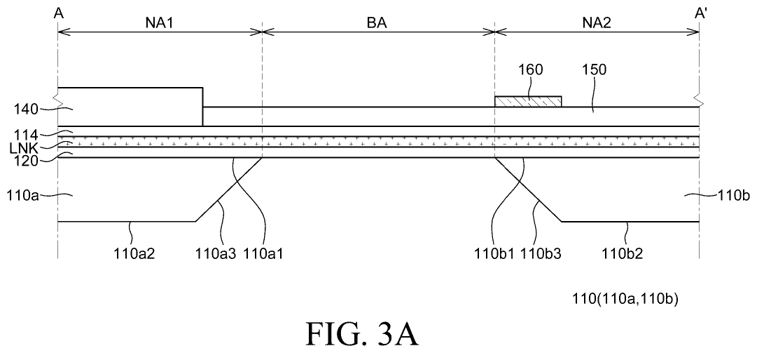

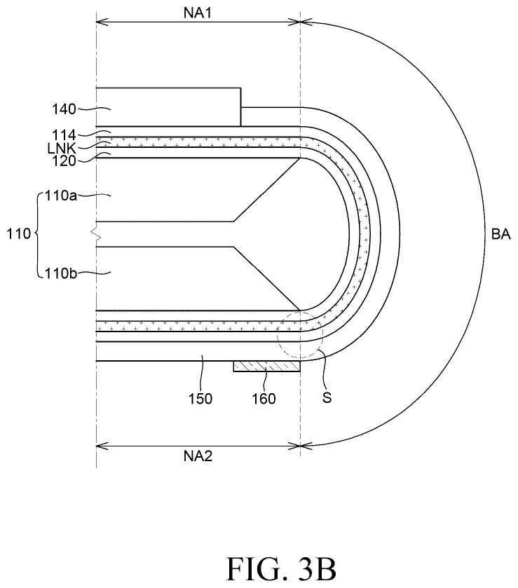

When the link line LNK formed in the bending area BA is bent, a tensile force is applied thereto. For example, the largest tensile force is applied to the link line LNK extending to the same direction as the bending direction (represented by an arrow) on the glass substrate 110 so that a crack may be generated. When the crack is severe, the line may be open. Accordingly, the rigid member 160 is disposed so as to be adjacent to the bending area BA on the link line LNK to minimize the tensile force to minimize generation of a crack. The rigid member will be described in detail with reference to FIGS. 3A and 3B.

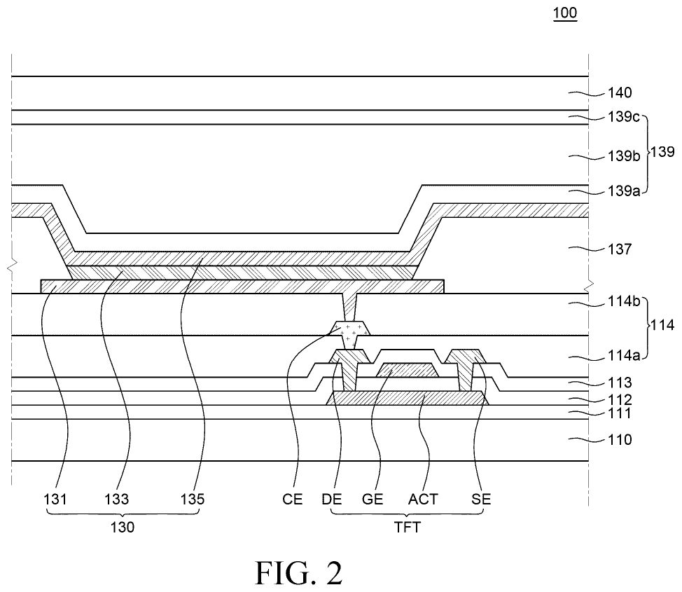

FIG. 2 is a cross-sectional view of an active area of a display device according to an exemplary embodiment of the present disclosure.

Referring to FIG. 2, the display device 100 includes a glass substrate 110, a thin film transistor TFT, a connection electrode CE, and a light emitting diode 130.

The glass substrate 110 serves to support and protect components of the display device 100 disposed thereabove. The glass substrate may be formed of glass.

A buffer layer 111 is disposed on the glass substrate 110. The buffer layer 111 may suppress permeation of moisture or other impurities through the glass substrate 110 and planarize a surface of the glass substrate 110. However, the buffer layer 111 is not an essential configuration and may be omitted depending on a type of a thin film transistor TFT disposed on the glass substrate 110.

The thin film transistor TFT is disposed on the glass substrate 110. The thin film transistor TFT may drive the light emitting diode 130. The thin film transistor TFT includes a gate electrode GE, a source electrode SE, a drain electrode DE, and a semiconductor layer ACT.

The semiconductor layer ACT is disposed on the buffer layer 111. When the thin film transistor TFT is driven, a channel is formed in the semiconductor layer ACT. The semiconductor layer ACT may be configured by amorphous silicon or polycrystalline silicon, but is not limited thereto. The polycrystalline silicon has a better mobility than that of amorphous silicon and has low power consumption and excellent reliability so as to be applied to the driving thin film transistor in the pixel.

Further, the semiconductor layer ACT may be configured by an oxide semiconductor. The oxide semiconductor has excellent mobility and uniformity. The oxide semiconductor may configure the semiconductor layer ACT with an indium tin gallium zinc oxide (InSnGaZnO) based material which is a quaternary metal oxide, an indium gallium zinc oxide (InGaZnO) based material, an indium tin zinc oxide (InSnZnO) based material, an indium aluminum zinc oxide (InAlZnO) based material, a tin gallium zinc oxide (SnGaZnO) based material, an aluminum gallium zinc oxide (AlGaZnO) based material, a tin aluminum zinc oxide (SnAlZnO) based material which are ternary metal oxides, an indium zinc oxide (InZnO) based material, a tin zinc oxide (SnZnO) based material, an aluminum zinc oxide (AlZnO) based material, a zinc magnesium oxide (ZnMgO) based material, a tin magnesium oxide (SnMgO) based material, an indium magnesium oxide (InMgO) based material, an indium gallium oxide (InGaO) based material, which are bimetallic oxides, an indium oxide (InO) based material, a tin oxide (SnO) based material, and a zinc oxide (ZnO), but a composition ratio of individual elements is not limited.

The semiconductor layer ACT may include a source region and a drain region including a p-type or n-type impurity, and a channel region between the source region and the drain region and further include a lightly doped region between the source region and the drain region which are adjacent to the channel region.

The source region and the drain region are areas where the impurities are highly doped and the source electrode SE and the drain electrode DE of the thin film transistor TFT may be connected thereto, respectively. As an impurity ion, a p-type impurity or an n-type impurity may be used. The p-type impurity may be one of boron (B), aluminum (Al), gallium (Ga), and indium (In) and the n-type impurity may be one of phosphorus (P), arsenic (As), and antimony (Sb).

The channel region of the semiconductor layer ACT may be doped with the n-type impurity or the p-type impurity in accordance with the NMOS or PMOS thin film transistor structure. As the thin film transistor included in the electroluminescent display device according to the exemplary embodiment of the present disclosure, the NMOS or the PMOS thin film transistor may be applied.

The first insulating layer 112 is an insulating layer for insulating the semiconductor layer ACT and the gate electrode GE and is configured by a single layer of silicon oxide (SiOx) or silicon nitride (SiNx) or multiple layers thereof and is disposed so as not to allow a current flowing through the semiconductor layer ACT to flow to the gate electrode GE. The silicon oxide has ductility which is lower than that of metal, but is better than that of the silicon nitride and may be formed by a single layer or multiple layers depending on the characteristic.

The gate electrode GE serves as a switch which turns on or off the thin film transistor TFT based on an electric signal transmitted from the outside through a gate line. The gate electrode may be configured by a single layer or multiple layers of copper (Cu), aluminum (Al), molybdenum (Mo), chrome (Cr), gold (Au), titanium (Ti), nickel (Ni), and neodymium (Nd) which are conductive metals or an alloy thereof, but is not limited thereto.

The source electrode SE and the drain electrode DE are connected to a data line and transmit an electric signal which is transmitted from the outside to the light emitting diode 130 from the thin film transistor TFT. The source electrode SE and the drain electrode DE may be configured by a single layer or multiple layers of metal materials such as copper (Cu), aluminum (Al), molybdenum (Mo), chrome (Cr), gold (Au), titanium (Ti), nickel (Ni), and neodymium (Nd) which are conductive metals or an alloy thereof, but are not limited thereto.

In order to insulate the gate electrode GE from the source electrode SE and the drain electrode DE, a second insulating layer 113 which is configured by a single layer or multiple layers of silicon oxide (SiOx) or silicon nitride (SiNx) may be disposed between the gate electrode GE and the source electrode SE and the drain electrode DE. The source electrode SE and the drain electrode DE are electrically connected to the semiconductor layer ACT through the contact holes of the first insulating layer 112 and the second insulating layer 113.

A passivation layer which is configured by an inorganic insulating layer such as silicon oxide SiOx or silicon nitride SiNx may be further disposed on the thin film transistor TFT. The passivation layer may serve to suppress unnecessary electrical connection between components above and below the passivation layer and suppress contamination or damage from the outside. However, the passivation layer may be omitted in accordance with a configuration and a characteristic of the thin film transistor TFT and the light emitting diode 130.

The thin film transistor TFT may be classified into an inverted staggered structure and a coplanar structure depending on the position of the components which configure the thin film transistor TFT. In the thin film transistor with an inverted staggered structure, a gate electrode is located on a side opposite to the source electrode and the drain electrode with respect to the semiconductor layer. As illustrated in FIG. 2, in the thin film transistor TFT with the coplanar structure, the gate electrode GE is located on the same side as the source electrode SE and the drain electrode DE with respect to the semiconductor layer ACT.

Even though in FIG. 2, the coplanar thin film transistor TFT has been illustrated, the display device 100 according to the present disclosure may include a thin film transistor with an inverted staggered structure without being limited thereto.

For the convenience of description, FIG. 2 illustrates only a driving thin film transistor among various thin film transistors which may be included in the display device 100. However, a switching thin film transistor and a capacitor may also be included in the display device 100. When a signal is applied from the gate line, the switching thin film transistor transmits a signal from the data line to the gate electrode of the driving thin film transistor. The driving thin film transistor transmits a current, which is transmitted through a power line by the signal transmitted from the switching thin film transistor, to the anode 131 and controls the emission by the current which is transmitted to the anode 131.

A planarization layer 114 is disposed on the thin film transistor TFT to protect the thin film transistor TFT, relieve a step generated due to the thin film transistor TFT, and reduce a parasitic capacitance generated between the thin film transistor TFT, the gate line and the data line, and the light emitting diodes 130.

The planarization layer 114 is an insulating layer which planarizes an upper portion of the glass substrate 110. The planarization layer 114 may be formed of an organic material and may be formed of one or more materials of acrylic resin, epoxy resin, phenolic resin, polyamide resin, polyimide resin, unsaturated polyester resin, polyphenylene resin, polyphenylenesulfide resin, and benzocyclobutene, but is not limited thereto.

The display device 100 according to the exemplary embodiment of the present disclosure may include a first planarization layer 114a and a second planarization layer 114b which are a plurality of planarization layers 114 which are sequentially laminated.

For example, the first planarization layer 114a may be disposed on the thin film transistor TFT and the second planarization layer 114b may be disposed on the first planarization layer 114a.

Further, a buffer layer may be disposed on the first planarization layer 114a. The buffer layer may be disposed so as to protect a component disposed on the first planarization layer 114a and for example, may be configured by a single layer of silicon nitride (SiNx) or silicon oxide (SiOx) or multiple layers of silicon nitride (SiNx) or silicon oxide (SiOx). The buffer layer may be omitted according to a configuration and a characteristic of the thin film transistor TFT and the light emitting diode 130.

The connection electrode CE is disposed through a contact hole formed in the first planarization layer 114a and the connection electrode CE is electrically connected to the thin film transistor TFT. That is, the connection electrode CE is an electrode for connecting the drain electrode DE of the thin film transistor TFT and the anode 131 of the light emitting diode 130. The connection electrode CE may be configured by multiple layers formed of a conductive material, such as copper (Cu), gold (Au), silver (Ag), aluminum (Al), molybdenum (Mo), nickel (Ni), titanium (Ti), chrome (Cr), or an alloy thereof, but is not limited thereto.

A passivation layer configured by an inorganic insulating layer, such as silicon oxide (SiOx) or silicon nitride (SiNx) may be further disposed on the first planarization layer 114a and the connection electrode CE. The passivation layer may serve to suppress unnecessary electrical connection between components and suppress contamination or damage from the outside. However, the passivation layer may be omitted in accordance with a configuration and a characteristic of the thin film transistor TFT and the light emitting diode 130.

The light emitting diode 130 is disposed on the second planarization layer 114b and includes an anode 131, an emission layer 133, and a cathode 135.

The anode 131 may be disposed on the second planarization layer 114b. The anode 131 is an electrode which serves to supply holes to the emission layer 133 and is connected to the connection electrode CE through the contact hole on the second planarization layer 114b to be electrically connected to the thin film transistor TFT.

For example, the anode 131 may be configured by indium tin oxide (ITO) and indium zinc oxide (IZO) which are transparent conductive materials, but is not limited thereto.

When the display device 100 according to the present disclosure is a top emission type which emits light to an upper portion on which the cathode 135 is disposed, the anode 131 may further include a reflective layer which allows the emitted light to be reflected from the anode 131 to be more smoothly emitted to an upper direction where the cathode 135 is disposed.

For example, the anode 131 may have a double-layered structure in which a transparent conductive layer configured by a transparent conductive material and a reflective layer are sequentially laminated or a triple-layered structure in which a transparent conductive layer, a reflective layer, and a transparent conductive layer are sequentially laminated. The reflective layer may be silver (Ag) or an alloy including silver.

A bank layer 137 is disposed on the anode 131 and the second planarization layer 114b. The bank layer 137 partitions an area in which light is actually emitted to define a pixel. The bank layer 137 may be formed by photolithography after forming a photoresist on the anode 131. The photoresist refers to a photosensitive resin whose solubility in a developer is changed by the action of light, and a specific pattern may be obtained by exposing and developing the photoresist. The photoresist may be classified into a positive photoresist and a negative photoresist. The positive photoresist is a photoresist whose solubility of the exposed portion in the developer is increased by the exposure. When the positive photoresist is developed, a pattern from which exposed portions are removed is obtained. The negative photoresist is a photoresist whose solubility of the exposed portion in the developer is significantly lowered by the exposure. When the negative photoresist is developed, a pattern from which non-exposed portions are removed is obtained.

In order to form an emission layer 133 of the light emitting diode 130, a fine metal mask (FMM) which is a deposition mask may be used. In order to suppress a damage which may be caused by contact with the deposition mask disposed on the bank layer 137 and maintain a predetermined distance between the bank layer 137 and the deposition mask, a spacer which is configured by one of polyimide, photoacryl, and benzocyclobutene (BCB) which are transparent organic materials may be disposed above the bank layer 137.

The emission layer 133 is disposed between the anode 131 and the cathode 135. The emission layer 133 serves to emit light and may include at least one of a hole injection layer (HIL), a hole transport layer (HTL), an organic layer, an electron transport layer (ETL), and an electron injection layer (EIL). Some components of the emission layer 133 may be omitted depending on the structure or the characteristic of the display device 100.

The hole injection layer is disposed on the anode 131 to smoothly inject the holes. The hole injection layer may be formed of any one or more of HAT-CN (dipyrazino[2,3-f:2′,3′-h]quinoxaline-2,3,6,7,10,11-hexacarbonitrile), CuPc (phthalocyanine), and NPD (N,N′-bis(naphthalene-1-yl)-N,N′-bis(phenyl)-2,2′-dimethylbenzidine).

The hole transport layer is disposed on the hole injection layer to smoothly transmit holes to the organic layer. For example, the hole transport layer may be formed of any one or more of NPD (N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), s-TAD (2,2′,7,7′-tetrakis(N,N-dimethylamino)-9,9-spirofluorene), and MTDATA (4,4′,4″-Tris(N-3-methylphenyl-N-phenyl-amino)-triphenylamine).

The organic layer is disposed on the hole transport layer and includes a material which emits specific color light to emit specific color light. The light emitting material may be formed using a phosphorescent material or a fluorescent material.

When the organic layer emits red light, an emitting peak wavelength may be in the range of 600 nm to 650 nm. The organic layer may include a host material including CBP (4,4′-bis(carbazol-9-yl)biphenyl) or mCP (1,3-bis(carbazol-9-yl)benzene) and may be formed of a phosphorescent material including a dopant material including one or more of PIQIr (acac)(bis(1-phenylisoquinoline) (acetylacetonate) iridium), PQIr (acac)(bis(1-phenylquinoline) (acetylacetonate) iridium), PQIr (tris(1-phenylquinoline) iridium), and PtOEP (octaethylporphyrin platinum). Alternatively, the organic layer may be formed of a fluorescent material including PBD:Eu(DBM)3(Phen) or perylene.

Here, the peak wavelength λ refers to a maximum wavelength of electroluminescence (EL). A wavelength at which organic layers configuring the organic layer emits unique light is referred to as photoluminescence (PL) and light emitted by the influence of the thickness or the optical characteristic of layers configuring the organic layers is referred to as emittance. In this case, electroluminescence (EL) refers to light which is finally emitted by the display device 100 and may be represented by a product of photoluminescence (PL) and emittance.

When the organic layer emits green light, an emitting peak wavelength is in the range of 520 nm to 540 nm. The organic layer may include a host material including CBP or mCP and may be formed of a phosphorescent material including a dopant material including Ir(ppy)₃(tris(2-phenylpyridine) iridium) such as Ir complex. Alternatively, the organic layer may be formed of a fluorescent material including Alq₃(tris(8-hydroxyquinolino)aluminum).

When the organic layer emits blue light, an emitting peak wavelength is in the range of 440 nm to 480 nm. The organic layer may include a host material including CBP or mCP and may be formed of a phosphorescent material including a dopant material including FIrPic(bis(3,5-difluoro-2-(2-pyridyl)phenyl-(2-carboxypyridyl) iridium). Alternatively, the organic layer may be formed of a fluorescent material including any one of spiro-DPVBi(4,4′-Bis(2,2-diphenyl-ethen-1-yl)biphenyl), DSA (1-4-di-[4-(N,N-di-phenyl)amino]styryl-benzene), PFO (polyfluorene) based polymer, and PPV (polyphenylenevinylene) based polymer.

The electron transport layer is disposed on the organic layer and serves to smoothly move the electrons to the organic layer. For example, the electron transport layer may be formed of any one or more of Liq (8-hydroxyquinolinolato-lithium), PBD (2-(4-biphenyl)-5-(4-tert-butylphenyl)-1,3,4-oxadiazole), TAZ (3-(4-biphenyl) 4-phenyl-5-tert-butylphenyl-1,2,4-triazole), spiro-PBD, BCP (2,9-Dimethyl-4,7-diphenyl-1,10-phenanthroline), and BAlq(bis(2-methyl-8-quinolinolate)-4-(phenylphenolato)aluminum).

The electron injection layer may be further disposed on the electron transport layer. The electron injection layer is an organic layer which smoothly injects the electrons from the cathode 135 and may be omitted depending on the structure and the characteristic of the display device 100. The electron injection layer may be a metal inorganic compound such as BaF2, LiF, NaCl, CsF, Li₂O, and BaO or any one or more organic compounds of HAT-CN (dipyrazino[2,3-f:2′,3′-h]quinoxaline-2,3,6,7,10,11-hexacarbonitrile), CuPc (phthalocyanine), and NPD (N,N′-bis(naphthalene-1-yl)-N,N′-bis(phenyl)-2,2′-dimethylbenzidine).

The electron blocking layer or the hole blocking layer which blocks the flow of holes or electrons may be further disposed in a position adjacent to the organic layer. When the electrons are injected into the organic layer, the electrons move from the organic layer to pass through the adjacent hole transport layer or when the holes are injected into the organic layer, the holes move from the organic layer to pass through the adjacent electron transport layer. Therefore, the electron blocking layer or the hole blocking layer suppresses this problem to improve the luminous efficiency.

The cathode 135 is disposed on the emission layer 133 to supply electrons to the emission layer 133. Since the cathode 135 needs to supply electrons, the cathode 135 may be configured by a metal material which is a conductive material having a low work function such as magnesium (Mg) or silver-magnesium (Ag:Mg), but is not limited thereto.

When the display device 100 is a top emission type, the cathode 135 may be formed of indium tin oxide (ITO), indium zinc oxide (IZO), indium tin zinc oxide (ITZO), zinc oxide (ZnO), and tin oxide (TiO) based transparent conductive oxide.

An encapsulation layer 139 may be disposed on the light emitting diode 130 to suppress oxidation or damage of the thin film transistor TFT and the light emitting diode 130 which are components of the display device 100, due to moisture, oxygen, or impurities introduced from the outside. For example, the encapsulation layer 139 may include a first encapsulation layer 139a, a second encapsulation layer 139b, and a third encapsulation layer 139c, but is not limited thereto.

At this time, the first encapsulation layer 139a and the third encapsulation layer 139c may be configured by inorganic films and the second encapsulation layer 139b may be configured by an organic film. Among the first encapsulation layer 139a, the second encapsulation layer 139b, and the third encapsulation layer 139c, the second encapsulation layer 139b is the thickest and may serve as a planarization layer.

The first encapsulation layer 139a may be disposed on the cathode 135 and may be disposed to be the most adjacent to the light emitting diode 130. The first encapsulation layer 139a may be formed of an inorganic insulating material on which low-temperature deposition can be performed. For example, the first encapsulation layer 139a may be configured by silicon nitride SiNx, silicon oxide (SiOx), silicon oxynitride (SiON), or aluminum oxide (Al₂O₃), but is not limited thereto. The first encapsulation layer 139a is deposited under a low temperature atmosphere so that during the deposition process, the damage of the emission layer 133 including an organic material which is vulnerable to the high temperature atmosphere may be suppressed.

The second encapsulation layer 139b may be formed to have a smaller area than that of the first encapsulation layer 139a. In this case, the second encapsulation layer 139b may be formed to expose both ends of the first encapsulation layer 139a. The second encapsulation layer 139b may serve as a buffer to relieve stress between the layers due to bending of the display device 100 and to enhance planarization performance.

For example, the second encapsulation layer 139b may be formed of an organic insulating material, such as acrylic resin, epoxy resin, polyimide, polyethylene, or silicon oxy carbon (SiOC), but the material of the second encapsulation layer is not limited thereto. For example, the second encapsulation layer 139b may be formed by an inkjet method, but is not limited thereto.

The third encapsulation layer 139c may be formed above the glass substrate 110 on which the second encapsulation layer 139b is formed so as to cover upper surfaces and side surfaces of the second encapsulation layer 139b and the first encapsulation layer 139a. At this time, the third encapsulation layer 139c may minimize or block the permeation of external moisture or oxygen into the first encapsulation layer 139a and the second encapsulation layer 139b. For example, the third encapsulation layer 139c may be configured by an inorganic insulating material, such as silicon nitride SiNx, silicon oxide SiOx, silicon oxynitride SiON, or aluminum oxide Al₂O₃, but is not be limited thereto.

A barrier film may be further disposed on the encapsulation layer 139. The barrier film may delay the permeation of oxygen and moisture from the outside. The barrier film is configured as a film having translucency and both-sided adhesiveness and may be configured by any one insulating material of olefin based, acrylic, and silicon based insulating materials. Alternatively, the barrier film which is configured by any one material of cycloolefin polymer (COP), cycloolefin copolymer (COC), and polycarbonate (PC) may be further laminated, but is not limited thereto.

The polarizer 140 is disposed on the encapsulation layer 139 to selectively transmit light to reduce the reflection of external light which is incident onto the glass substrate 110. Specifically, various metal materials applied to the thin film transistor TFT, the wiring line, and the light emitting diode 130 may be disposed on the glass substrate 110. Therefore, the external light incident onto the glass substrate 110 may be reflected from the metal material so that the visibility of the display device 100 may be reduced due to the reflection of the external light. In contrast, when the polarizer 140 is disposed, the polarizer 140 suppresses the reflection of the external light so that the outdoor visibility of the display device 100 may be increased. However, the polarizer 140 may be omitted depending on an implementation example of the display device 100, but it is not limited thereto.

FIG. 3A is a cross-sectional view of a state before being bent taken along A-A′ of FIG. 1. FIG. 3B is a cross-sectional view of a bent state taken along A-A′ of FIG. 1. In FIGS. 3A and 3B, for the convenience of illustration, among various components of the display device 100, only a first glass substrate 110a, a second glass substrate 110b, an etch stop layer 120, a link line LNK, a planarization layer 114, a polarizer 140, a micro coating layer 150, and a rigid member 160 are schematically illustrated.

Referring to FIGS. 3A and 3B, the glass substrate 110 includes a first glass substrate 110a disposed in the first non-active area NA1 adjacent to the active area AA and a second glass substrate 110b disposed in the second non-active area NA2 extending from the bending area BA. In the meantime, on the drawing, it is illustrated that the first glass substrate 110a and the second glass substrate 110b are spaced apart from each other with the bending area BA therebetween, but the first glass substrate 110a and the second glass substrate 110b may be at least partially connected.

In the meantime, when a mother glass substrate is etched, a hole and a cell are separated to form the first glass substrate 110a and the second glass substrate 110b of the glass substrate 110. That is, the glass substrate 110 of the bending area BA is selectively removed to be simultaneously formed to form a structure in which a bezel is bendable. For example, a process of forming the bending area BA on the glass substrate 110 will be explained. A mask is formed on a rear surface of a mother glass substrate and a part of the mask is removed to form a hole. At this time, a process of forming a hole may be referred to as a process of removing a mask from the glass substrate by cutting the mask with laser and separating a hole and a cell from the mother glass substrate. Next, after primarily etching a part of the glass substrate through a mask in accordance with a portion in which the bending area BA is to be formed, the mask is removed and the entire rear surface of the glass substrate may be etched. After reducing a thickness of the rear surface of the glass substrate, a primarily etched part is completely removed to form the bending area BA on the glass substrate 110.

The first glass substrate 110a may be disposed in the active area AA and the first non-active area NA1 adjacent to the active area AA. The first glass substrate 110a may be disposed to be adjacent to the bending area BA extending from the first non-active area NA1.

The first glass substrate 110a may include a top surface 110al which is in contact with the etch stop layer 120, a bottom surface 110a2 which is opposite to the top surface 110a1, and a side surface 110a3 which connects an end of the top surface 110al adjacent to the bending area BA and an end of the bottom surface 110a2.

The end of the top surface 110a1 of the first glass substrate 110a may be disposed to be more adjacent to the bending area BA than the end of the bottom surface 110a2. Therefore, the side surface 110a3 may be defined by an inclined surface which connects the end of the top surface 110a1 and the end of the bottom surface 110a2. An inclination angle of the side surface 110a3 may be 45 degrees, but is not limited thereto. The side surface 110a3 may be formed by an inclined or concave surface.

The second glass substrate 110b is disposed in the second non-active area NA2. That is, the second glass substrate 110b may be disposed in the second non-active area NA2 extending from the bending area BA. Therefore, one end of the second glass substrate 110b may be in contact with the bending area BA.

An end of a top surface 110b1 of the second glass substrate 110b may be disposed to be more adjacent to the bending area BA than the end of the bottom surface 110b2. An inclination angle of the side surface 110b3 may be 45 degrees, but is not limited thereto. The side surface 110b3 adjacent to the bending area BA may be formed by an inclined or concave surface.

The first glass substrate 110a and the second glass substrate 110b may have a thickness of 0.01 mm to 1.0 mm to maintain flatness of the top surfaces 110a1 and 110b1 or block permeation of moisture or oxygen to the display device 100. Desirably, the thickness of the first glass substrate 110a and the second glass substrate 110b may be 100 μm. However, the thickness of the first glass substrate 110a and the second glass substrate 110b is not limited thereto and may vary depending on a design condition of the display device 100.

The etch stop layer 120 is disposed so as to overlap the bending area BA. At this time, a bottom surface of the etch stop layer 120 may be exposed from the first glass substrate 110a and the second glass substrate 110b in the bending area BA. Specifically, the etch stop layer 120 may be a configuration for suppressing a damage due to the etching when an etching process required to form the first glass substrate 110a and the second glass substrate 110b is performed. That is, the etch stop layer 120 may protect a configuration located above the etch stop layer 120 during a process of forming side surfaces 110a3 and 110b3 of the first glass substrate 110a and the second glass substrate 110b. Accordingly, the etch stop layer 120 may be disposed so as to overlap the bending area BA of the display device 100. The etch stop layer 120 may have an area larger than an area overlapping the top surface 110a1 of the first glass substrate 110a and the top surface 110b1 of the second glass substrate 110b or have an area larger than the bending area BA.

Further, the etch stop layer 120 may be disposed in the bending area BA and overlap the top surface 110a1 of the first glass substrate 110a extending to one side of the bending area BA and overlap the top surface 110b1 of the second glass substrate 110b extending to the other side of the bending area BA. That is, the etch stop layer 120 may be disposed on the first glass substrate 110a of the first non-active area NA1 and the second glass substrate 110b of the second non-active area NA2. Moreover, the etch stop layer 120 may be disposed only in the non-active area NA corresponding to the bending area BA and may also be disposed in the entire first non-active area NA1 including the active area AA, but is not limited thereto.

The etch stop layer 120 may be configured by an organic material and specifically, configured by a material resistant to a glass etchant and a material having a corrosion resistance. For example, as the etchant for glass etching, an etchant including phosphoric acid (H₃PO₄) or hydrofluoric acid (HF) may be used. The etch stop layer 120 may include any one of silicon based organic material, urethane, polyimide, photoacrylic, chromium (Cr), aluminum (Al), platinum (Pt), gold (Au), and nickel (Ni).

Further, the etch stop layer 120 may be formed by spraying a material in a position set by a mechanical method, such as slit coater, inkjet, or dispenser or formed by a patterning process using a photolithographic mask. At this time, a thickness of the etch stop layer 120 may be 1 μm to 5 μm. Desirably, the thickness of the etch stop layer 120 may be 2 μm to 3 μm, but is not limited thereto. In the meantime, when the thickness of the etch stop layer 120 is less than 1 μm, the etch stop layer 120 is damaged during the glass etching process of forming side surfaces 110a3 and 110b3 of the first glass substrate 110a and the second glass substrate 110b. Therefore, the etch stop layer cannot protect a configuration located above the etch stop layer 120. Further, when the thickness of the etch stop layer 120 exceeds 5 μm, there may be a risk that the etch stop layer serves as an element which hinders the bending or is damaged due to the compressive force during the bending.

Accordingly, the etch stop layer 120 disposed between the first glass substrate 110a and the second glass substrate 110b and the link line LNK is included in the bending area BA. Therefore, the damage of the display device 100 by the glass etching process of forming the side surfaces 110a3 and 110b3 of the first glass substrate 110a and the second glass substrate 110b may be suppressed.

The link line LNK may be disposed on the etch stop layer 120 across the bending area BA. The link line LNK may be disposed on the same layer as the connection electrode CE. The link line LNK is formed of a conductive material and may be formed of a conductive material having an excellent ductility to reduce the crack generated at the time of bending the glass substrate 110. For example, the link line LNK may be formed of a conductive material having excellent ductility such as gold (Au), silver (Ag), and aluminum (Al) and formed of one of various conductive materials used in the active area AA. The link line LNK may also be configured by molybdenum (Mo), chrome (Cr), titanium (Ti), nickel (Ni), neodymium (Nd), copper (Cu), and an alloy of silver (Ag), and magnesium (Mg). Further, the link line LNK may be configured by a multi-layered structure including various conductive materials and for example, configured by a triple layered structure of titanium (Ti)/aluminum (Al)/titanium (Ti), but the structure of the link line LNK according to the present disclosure is not limited thereto.

The planarization layer 114 extends on the bending area BA to be disposed on the link line LNK.

The planarization layer 114 is an organic layer and may have a structure in which the second planarization layer 114b is disposed to extend to planarize a top surface of the link line LNK and adjust a thickness and the first planarization layer 114a may not extend. In the meantime, when the connection electrode CE is not disposed and the drain electrode DE is directly connected to the anode 131, the link line LNK may be the same layer as the drain electrode DE or the source electrode SE and may be implemented as one planarization layer. Even though it is not illustrated in the drawing, the bank layer 137 may also be disposed to extend to the bending area BA.

The polarizer 140 is disposed on the first glass substrate 110a. The polarizer 140 is disposed on the first glass substrate 110a and may be in contact with the micro coating layer 150 in the first non-active area NA1.

The micro coating layer 150 is disposed so as to overlap at least a part of the first non-active area NA1 and the second non-active area NA2 and is disposed on the link line LNK in the bending area BA. The micro coating layer 150 may be disposed to extend to the first non-active area NA1 to be in contact with the polarizer 140.

Since a tensile force is applied to a link line LNK disposed on the etch stop layer 120 at the time of bending to cause minute crack, the micro coating layer 150 may be formed by coating a position to be bent with a resin with a small thickness to protect the link line LNK. At this time, the micro coating layer may be configured by resin and for example, may be configured by an acrylic material or urethane acrylate, but is not limited thereto.

The micro coating layer 150 may adjust a neutral plane of the bending area BA. The neutral plane means a virtual plane that is not stressed because the compressive force and the tensile force applied to the structure are canceled each other when the structure is bent. When two or more structures are laminated, a virtual neutral plane may be formed between structures. When the entire structure is bent in one direction, structures disposed in the bending direction with respect to the neutral plane are compressed by the bending so that a compressive force is applied thereto. In contrast, the structures which are disposed in an opposite direction to the bending direction with respect to the neutral plane are stretched due to the bending so that a tensile force is applied thereto. Normally, when the structures are applied with the tensile force between the compressive force and the tensile force, the structures are more susceptible, so that when the tensile force is applied, the structures are more likely to be cracked.

The etch stop layer 120 disposed on the lower portion with respect to the neutral plane is compressed to be applied with the compressive force and the link line LNK disposed on the upper portion may be applied with the tensile force so that the cracks may be generated due to the tensile force. Accordingly, in order to minimize the tensile force applied to the link line LNK, the micro coating layer 150 may be located on the neutral plane.

The micro coating layer 150 is disposed on the bending area BA to raise the neutral plane to the upward direction and the neutral plane is formed in the same position as the wiring line or the wiring line is disposed to be higher than the neutral plane. Therefore, the stress is not applied or the compressive force is applied at the time of bending, so that the crack may be suppressed. A modulus of the micro coating layer 150 may be 50 MPa to 200 MPa.

The rigid member 160 is disposed on the micro coating layer 150 to be adjacent to the bending area BA to overlap at least a part of the second glass substrate 110b. Specifically, the rigid member 160 may be disposed so as to overlap the end of the top surface 110b1 of the second glass substrate 110b and overlap the side surface 110b3 of the second glass substrate 110b on the micro coating layer 150.

Moreover, one end of the rigid member 160 which is adjacent to the bending area BA may be disposed so as to match an end of the top surface 110b1 of the second glass substrate 110b. The other end of the rigid member 160 may be disposed so as to match an end of the bottom surface 110b2 of the second glass substrate 110b.

In the meantime, when one end of the rigid member 160 is disposed inside the bending area BA more than an end of the top surface 110b1 of the second glass substrate 110b, that is, is biased to the left side with respect to a state illustrated in the drawing, a deformation of the micro coating layer 150 may be suppressed. However, a magnitude of force required for bending is increased so that it is hard to bend the bezel.

Further, when one end of the rigid member 160 is disposed outside the bending area BA more than an end of the top surface 110b1 of the second glass substrate 110b, that is, is biased to the right side with respect to a state illustrated in the drawing, a deformation of the micro coating layer 150 may be insignificantly suppressed. Accordingly, one end of the rigid member 160 which is adjacent to the bending area BA may be disposed so as to match an end of the top surface 110b1 of the second glass substrate 110b.

When the rigid member 160 is bent, more stress may be applied to the link line LNK due to the deformation of the micro coating layer 150 so that a deformation of the micro coating layer 150 in a corner portion S to which the stress is added may be suppressed. At this time, the rigid member 160 may include any one of a polymer material, a metal material, and a ceramic material having a higher rigidity than that of the micro coating layer 150. For example, in consideration of adhesiveness with the micro coating layer 150, as the rigid member 160, an acrylic polymer material is the most desirable. The acrylic polymer material can increase the modulus by increasing the crosslinking density (structural densification) by adding a multifunctional group to the same material. Further, the rigid member 160 may have a high adhesiveness with a metal material, such as stainless steel, aluminum, and titanium, due to the nature of the material.

A thickness of the rigid member 160 may be 10% to 50% of the thickness of the micro coating layer 150. For example, when the thickness of the micro coating layer 150 is 10 μm, the thickness of the rigid member 160 may be 2 μm.

Further, the modulus of the rigid member 160 may be 20 times to 200 times the modulus of the micro coating layer 150. Desirably, when the modulus of the micro coating layer 150 is 109 MPa, the modulus of the rigid member 160 may be 2180 MPa, but is not limited thereto. For example, the largest tensile force is applied to the link line LNK extending to the same direction as the bending direction during the bending so that a crack may be generated. When the crack is severe, the line may be open. That is, during the bending, the thickness of the micro coating layer 150 is changed in the corner portion S of the second glass substrate 110b so that the link line LNK is applied with stress.

Accordingly, the rigid member 160 is disposed to be adjacent to the bending area BA on the micro coating layer 150 which overlaps the link line LNK so that the deformation of the micro coating layer 150 is reduced to reduce the stress of the link line LNK and minimize the tensile stress to minimize the generation of the crack.

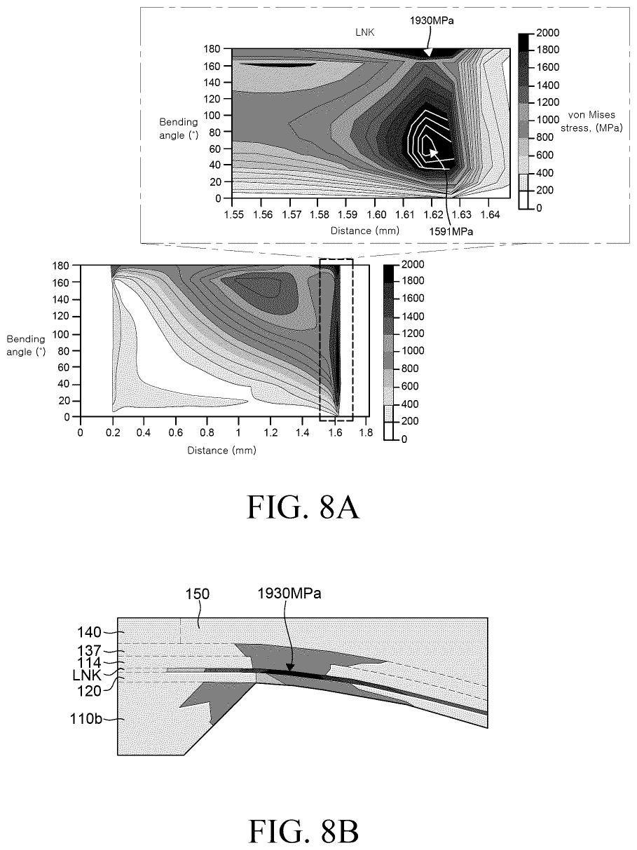

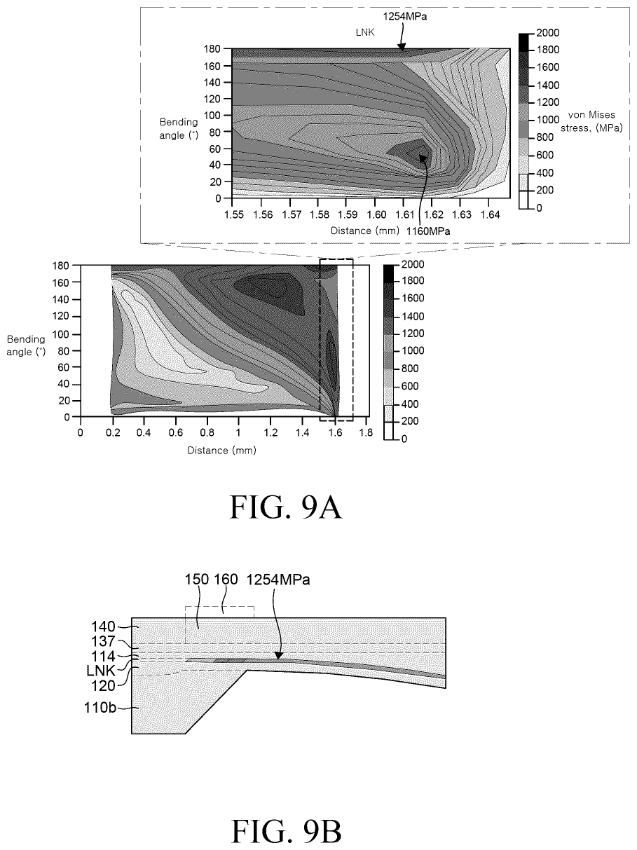

Hereinafter, the effect of the display device according to the exemplary embodiment of the present disclosure will be described with reference to FIGS. 8A to 9B together.

FIGS. 8A and 8B are simulation results for a stress of a display device according to a comparative embodiment. FIGS. 9A and 9B are simulation results for a stress of a display device according to an exemplary embodiment of the present disclosure. Here, the display device according to the comparative embodiment does not use a rigid member 160 as compared with the display device 100 according to the exemplary embodiment of the present disclosure.

For example, the common conditions of the comparative embodiment and the display device 100 according to the exemplary embodiment are as represented in Table 1.

TABLE 1

| Component | Thickness (μm) | Modulus (MPa) |
|---|---|---|
| Glass substrate 110 | 200 | 60000 |
| Etch stop layer 120 | 2.0 | 7400 |
| Link line LNK | 0.7 | 75000 |
| Planarization layer 114 | 2.3 | — |
| Bank layer 137 | 2.5 | — |
| Polarizer 140 | — | 2700 |
| Micro coating layer 150 | 10 | 109 |

Additionally, in the display device 100 according to the exemplary embodiment of the present disclosure, a thickness of the rigid member 160 is 2 μm and a modulus of the rigid member 160 is 2180 MPa.

On the graph, the X-axis is a distance (mm) from the first glass substrate 110a of the display device 100 to the second glass substrate 110b and the Y-axis is a bending angle (°) and a contour line to be measured indicates von Mises stress (MPa). Here, the distance 0 to 0.2 mm along the X-axis is a left part of the display device 100 (the first glass substrate 110a), 0.2 mm to 1.6 mm is a bending area BA, and 1.6 mm to 1.8 mm is a right part (the second glass substrate 110b). When the bezel of the display device is bent, the largest stress is applied to the link line in the right bending area. Therefore, in the enlarged view, in the right bending area BA part (1.55 mm to 1.64 mm), a stress applied to the link line LNK is specifically illustrated according to a bending angle along the Y axis.

Here, the von Mises stress represents other stress, that is, the tension and compression represent a direction and a stress, but the von Mises stress has a scalar form without a direction so that it means a complex stress value, such as tension and compression. Accordingly, when the von Mises stress reaches a yield stress, it is analyzed that the material is yielded and when the von Mises stress is lowered, it is analyzed that it is far away from the yield stress value.

FIGS. 8A and 8B illustrate a von Mises stress value applied to a link line according to a bending angle on a plan view and a cross-sectional view of a display device according to a comparative embodiment. FIGS. 9A and 9B illustrate a von Mises stress value applied to a link line according to a bending angle on a plan view and a cross-sectional view of a display device 100 according to an exemplary embodiment of the present disclosure.

Referring to FIGS. 8A and 8B, when the bezel is bent, that is, when a 1.61 mm to 1.63 mm portion of the display device is bent by 180°, it is confirmed that the von Mises stress value applied to the link line LNK located at the end of the second glass substrate 110b is 1930 MPa. When it is bent by 60°, it is confirmed that the von Mises stress value applied to the link line LNK located at the end of the second glass substrate 110b is 1591 MPa.

Referring to FIGS. 9A and 9B, when the bezel is bent, that is, when a 1.61 mm to 1.63 mm portion of the display device is bent by 180°, it is confirmed that the von Mises stress value applied to the link line LNK located at the end of the second glass substrate 110b is 1254 MPa. When it is bent by 60°, it is confirmed that the von Mises stress value applied to the link line LNK located at the end of the second glass substrate 110b is 1160 MPa.

That is, it was confirmed that in the display device 100 according to the exemplary embodiment, a maximum stress was reduced by approximately 35.0%.

As a result, as a simulation result, in the display device of the comparative embodiment, when the bezel was bent, a micro coating layer was deformed in the bending area BA of the second glass substrate 110b so that a stress was increased in a lower layer of the micro coating layer. It is understood that as the stress increases thereby, a very high stress is locally applied to the corner portion S of the second glass substrate 110b of the bending area BA and a stress concentrated on the link line LNK is very likely to cause a crack.

Accordingly, in the display device 100 according to the exemplary embodiment of the present disclosure, when the bezel is bent, the stress may be surely reduced. Specifically, in the display device 100 according to the exemplary embodiment of the present disclosure, the rigid member 160 is disposed on the micro coating layer 150 to be adjacent to the bending area BA. At this time, the rigid member 160 is disposed on the micro coating layer 150 so as to overlap at least a part of the second glass substrate 110b to suppress deformation of the micro coating layer 150. Accordingly, in the display device 100 according to the exemplary embodiment of the present disclosure, the rigid member 160 is disposed to suppress the deformation of the micro coating layer 150, thereby reducing a stress due to the bending.

Further, in the display device 100 according to the exemplary embodiment of the present disclosure, the rigid member 160 having a rigidity higher than that of the micro coating layer 150 is disposed to reduce the stress of the link line LNK. Specifically, in the display device 100 according to the exemplary embodiment of the present disclosure, the rigid member 160 having a modulus which is 200 times higher than that of the micro coating layer 150 is disposed to reduce the stress concentrated on the link line LNK. Accordingly, in the display device 100 according to the exemplary embodiment of the present disclosure, the rigid member 160 having a high rigidity is disposed to reduce the stress of the link line LNK and alleviate a stress caused by expansion and contraction which may occur in a high temperature and low temperature environment of the bending area. Therefore, the reliability of the display device 100 may be improved.

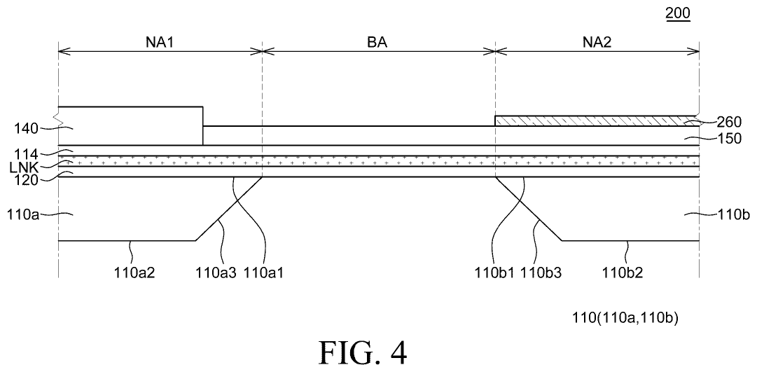

FIG. 4 is a cross-sectional view of a display device according to another exemplary embodiment of the present disclosure. In FIG. 4, for the convenience of illustration, only a first glass substrate 110a, a second glass substrate 110b, an etch stop layer 120, a link line LNK, a planarization layer 114, a polarizer 140, a micro coating layer 150, and a rigid member 260 are schematically illustrated. The display device 200 illustrated in FIG. 4 is substantially the same as the display device 100 illustrated in FIGS. 1 to 3B except for a rigid member 260, so that a redundant description may be omitted or simplified.

Referring to FIG. 4, the display device 200 according to another exemplary embodiment of the present disclosure may include a pad unit PAD disposed on the second glass substrate 110b in the second non-active area NA2. At this time, the rigid member 260 is disposed to extend to an end of the micro coating layer 150 toward the pad unit PAD. At this time, the rigid member 260 is disposed on the micro coating layer 150 so as to overlap the second glass substrate 110b to suppress deformation of the micro coating layer 150.

Specifically, the rigid member 260 may be disposed on the micro coating layer 150 to be adjacent to the bending area BA so as to overlap the second glass substrate 110b. The rigid member 260 may be disposed so as to overlap the end of the top surface 110b1 of the second glass substrate 110b and overlap the micro coating layer 150 on the second glass substrate 110b. That is, the rigid member 260 may be disposed so as to overlap the second non-active area NA2 excluding the first non-active area NA1 and the bending area BA.

Further, one end of the rigid member 260 which is adjacent to the bending area BA may be disposed so as to match an end of the top surface 110b1 of the second glass substrate 110b. The other end of the rigid member 260 may be disposed so as to match an end of the micro coating layer 150 on the second glass substrate 110b.

In the meantime, when one end of the rigid member 260 is disposed to be inside the bending area BA more than an end of the top surface 110b1 of the second glass substrate 110b, that is, is biased to the left side with respect to a state illustrated in the drawing, a deformation of the micro coating layer 150 may be suppressed. However, a magnitude of force required for bending is increased so that it is hard to bend the bezel.

Further, when one end of the rigid member 260 is disposed outside the bending area BA more than an end of the top surface 110b1 of the second glass substrate 110b, that is, is biased to the right side with respect to a state illustrated in the drawing, a deformation of the micro coating layer 150 may be insignificantly suppressed. Accordingly, one end of the rigid member 260 which is adjacent to the bending area BA may be disposed so as to match an end of the top surface 110b1 of the second glass substrate 110b.

When the rigid member 260 is bent, the stress may be further applied to the link line LNK due to the deformation of the micro coating layer 150 so that a deformation of the micro coating layer 150 in a portion to which the stress is applied may be suppressed. At this time, the rigid member 260 may include any one of a polymer material, a metal material, and a ceramic material having a higher rigidity than that of the micro coating layer 150. For example, in consideration of adhesiveness with the micro coating layer 150, as the rigid member 260, an acrylic polymer material is the most desirable. The acrylic polymer material may increase the modulus by increasing the crosslinking density (structural densification) by adding a multifunctional group to the same material. Further, the rigid member 260 may have a high adhesiveness with a metal material, such as stainless steel, aluminum, and titanium, due to the nature of the material.

A thickness of the rigid member 260 may be 10% to 50% of the thickness of the micro coating layer 150. For example, when the thickness of the micro coating layer 150 is 10 μm, the thickness of the rigid member 260 may be 2 μm.

Further, the modulus of the rigid member 260 may be 20 times to 200 times the modulus of the micro coating layer 150. Desirably, when the modulus of the micro coating layer 150 is 109 MPa, the modulus of the rigid member 260 may be 2180 MPa, but is not limited thereto.

The rigid member 260 is disposed to be adjacent to the bending area BA on the micro coating layer 150 so that the deformation of the micro coating layer 150 is reduced to reduce the stress of the link line LNK and minimize the tensile force to minimize the generation of the crack.

Accordingly, in the display device 200 according to another exemplary embodiment of the present disclosure, the rigid member 260 is disposed to extend to an end of the micro coating layer 150 toward the pad unit PAD to suppress the deformation of the micro coating layer 150, thereby reducing a stress due to the bending.

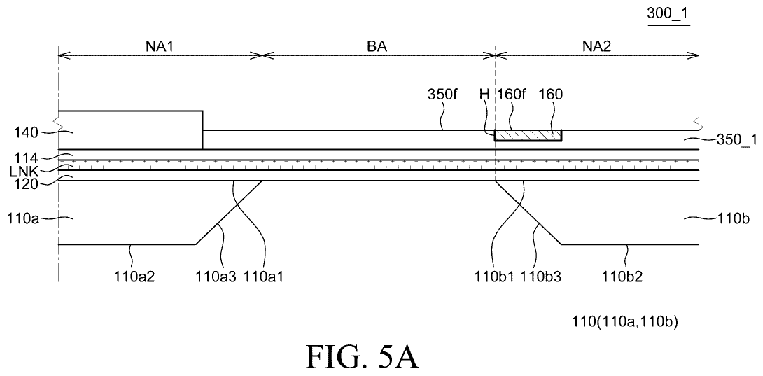

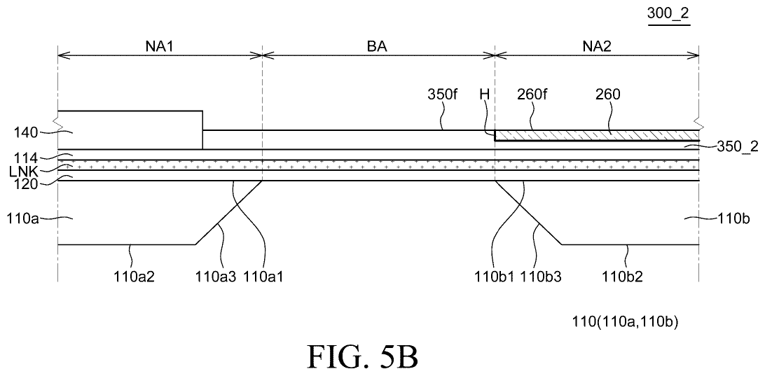

FIGS. 5A and 5B are cross-sectional views of a display device according to still another exemplary embodiment of the present disclosure. In FIGS. 5A and 5B, for the convenience of illustration, only a first glass substrate 110a, a second glass substrate 110b, an etch stop layer 120, a link line LNK, a planarization layer 114, a polarizer 140, micro coating layers 350_1 and 350_2, and rigid members 160 and 260 are schematically illustrated. A display device 300_1 illustrated in FIG. 5A is substantially the same as the display device 100 illustrated in FIGS. 3A and 3B except for a micro coating layer 350_1 and a display device 300_2 illustrated in FIG. 5B is substantially the same as the display device 200 illustrated in FIG. 4 except for a micro coating layer 350_2. Therefore, a redundant description will be omitted or simplified.

Referring to FIG. 5A, the micro coating layer 350_1 includes a groove H which is recessed from a top surface 350f so as to accommodate the rigid member 160. Therefore, the rigid member 160 may be disposed in the groove H. At this time, a top surface 160f of the rigid member 160 is coplanar with a top surface 350f of the micro coating layer 350_1 or may protrude from the top surface 350f of the micro coating layer 350_1. That is, the top surface 160f of the rigid member 160 may be disposed to be lower than a top surface of the polarizer 140.

The groove H of the micro coating layer 350_1 is formed to be adjacent to the bending area BA to overlap at least a part of the second glass substrate 110b. Specifically, the groove H of the micro coating layer 350_1 is formed so as to overlap an end of the top surface 110b1 of the second glass substrate 110b and overlap a side surface 110b3 of the second glass substrate 110b.

The groove H of the micro coating layer 350_1 may define a position in which the rigid member 160 is disposed. That is, the rigid member 160 is disposed according to a position in which the groove H of the micro coating layer 350_1 is formed. One end of the groove H of the micro coating layer 350_1 may be disposed so as to match an end of the top surface 110b1 of the second glass substrate 110b and the other end of the groove H of the micro coating layer 350_1 may be disposed so as to match an end of the bottom surface 110b2 of the second glass substrate 110b.

Accordingly, in a display device 300_1 according to another exemplary embodiment of the present disclosure, the rigid member 160 is disposed in the groove H of the micro coating layer 350_1 overlapping the link line LNK. Therefore, the deformation of the micro coating layer 350_1 is reduced to reduce a stress of the link line LNK and minimize a tensile force to minimize generation of cracks.

Referring to FIG. 5B, a micro coating layer 350_2 includes a groove H which is recessed from a top surface 350f so as to accommodate the rigid member 260. At this time, the rigid member 260 is disposed in the groove H and extends to an end of the micro coating layer 350_2 toward the pad unit PAD. At this time, a top surface 260f of the rigid member 260 is coplanar with as a top surface 350f of the micro coating layer 350_2 or may protrude from the top surface 350f of the micro coating layer 350_2. That is, the top surface 260f of the rigid member 260 may be disposed to be lower than a top surface of the polarizer 140.

The groove H of the micro coating layer 350_2 is adjacent to the bending area BA to overlap the second glass substrate 110b. Specifically, the groove H of the micro coating layer 350_2 may be formed to match and overlap an end of the top surface 110b1 of the second glass substrate 110b.

Further, the groove H of the micro coating layer 350_2 may define a position in which the rigid member 260 is disposed. That is, the rigid member 260 is disposed according to a position in which the groove H of the micro coating layer 350_2 is formed. One end of the groove H of the micro coating layer 350_2 may be formed so as to match an end of the top surface 110b1 of the second glass substrate 110b and the other end of the groove H of the micro coating layer 350_2 may be formed to an end of the micro coating layer 350_2 on the second glass substrate 110b.

Accordingly, in a display device 300_2 according to another exemplary embodiment of the present disclosure, the rigid member 260 is disposed in the groove H of the micro coating layer 350_2 overlapping the link line LNK. Therefore, the deformation of the micro coating layer 350_2 is reduced to reduce a stress of the link line LNK and minimize a tensile force to minimize generation of cracks.

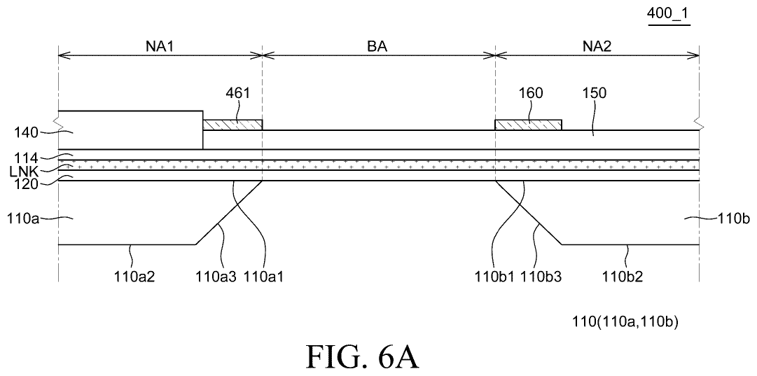

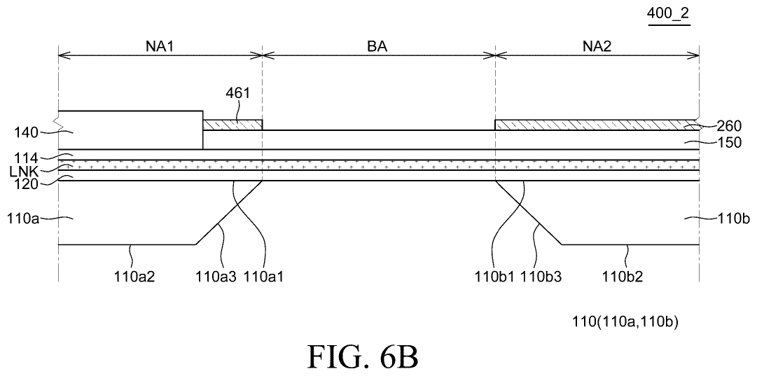

FIGS. 6A and 6B are cross-sectional views of a display device according to another exemplary embodiment of the present disclosure. In FIGS. 6A and 6B, for the convenience of illustration, only a first glass substrate 110a, a second glass substrate 110b, an etch stop layer 120, a link line LNK, a planarization layer 114, a polarizer 140, a micro coating layer 150, rigid members 160 and 260, and an auxiliary rigid member 461 are schematically illustrated. A display device 400_1 illustrated in FIG. 6A is substantially the same as the display device 100 illustrated in FIGS. 3A and 3B except for an auxiliary rigid member 461 and a display device 400_2 illustrated in FIG. 6B is substantially the same as the display device 200 illustrated in FIG. 4 except for an auxiliary rigid member 461. Therefore, a redundant description will be omitted or simplified.

Referring to FIGS. 6A and 6B, the auxiliary rigid member 461 is disposed on the micro coating layer 150 to be adjacent to the bending area BA so as to overlap at least a part of the first glass substrate 110a. At this time, the auxiliary rigid member 461 may serve to suppress deformation of the micro coating layer 150 by assisting the rigid members 160 and 260.

Specifically, the auxiliary rigid member 461 may be disposed on the micro coating layer 150 to be adjacent to the bending area BA so as to overlap the first glass substrate 110a and may be disposed so as to overlap an end of the top surface 110a1 and the side surface 110a3 of the first glass substrate 110a. That is, the auxiliary rigid member 461 may be disposed so as to overlap the first non-active area NA1 and the rigid members 160 and 260 may be disposed so as to overlap the second non-active area NA2. The auxiliary rigid member 461 and the rigid members 160 and 260 may be disposed on the micro coating layer 150 in an area excluding the bending area BA.

Further, an end of the auxiliary rigid member 461 adjacent to the bending area BA may be disposed to be in contact with the polarizer 140 and the other end of the auxiliary rigid member 461 may be disposed so as to match an end of the top surface 110a1 of the first glass substrate 110a.

In the meantime, when the other end of the auxiliary rigid member 461 is disposed inside the bending area BA more than an end of the top surface 110a1 of the first glass substrate 110a, that is, is biased to the right side with respect to a state illustrated in the drawing, a deformation of the micro coating layer 150 may be suppressed. However, a magnitude of force required for bending is increased so that it is hard to bend the bezel. Accordingly, the other end of the auxiliary rigid member 461 which is adjacent to the bending area BA may be disposed so as to match an end of the top surface 110a1 of the first glass substrate 110a.

The auxiliary rigid member 461 may include any one of a polymer material, a metal material, and a ceramic material having a higher rigidity than that of the micro coating layer 150. For example, in consideration of adhesiveness with the micro coating layer 150, as the auxiliary rigid member 461, an acrylic polymer material is the most desirable. The acrylic polymer material may increase the modulus by increasing the crosslinking density (structural densification) by adding a multifunctional group to the same material. Further, the rigid member 260 may have a high adhesiveness with a metal material, such as stainless steel, aluminum, and titanium, due to the nature of the material.

A thickness of the auxiliary rigid member 461 may be 10% to 50% of the thickness of the micro coating layer 150. For example, when the thickness of the micro coating layer 150 is 10 μm, the thickness of the auxiliary rigid member 461 may be 2 μm.

Further, the modulus of the auxiliary rigid member 461 may be 20 times to 200 times the modulus of the micro coating layer 150. Desirably, when the modulus of the micro coating layer 150 is 109 MPa, the modulus of the auxiliary rigid member 461 may be 2180 MPa, but is not limited thereto.

Accordingly, in display devices 400_1 and 400_2 according to another exemplary embodiment of the present disclosure, the rigid members 160 and 260 and the auxiliary rigid member 461 are disposed to be adjacent to the bending area BA on the micro coating layer 150. Therefore, the deformation of the micro coating layer 150 is reduced to reduce the stress of the link line LNK and minimize the tensile force to minimize the generation of the crack.

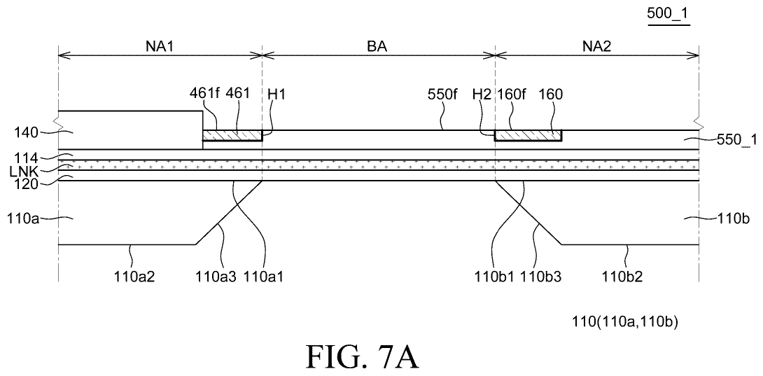

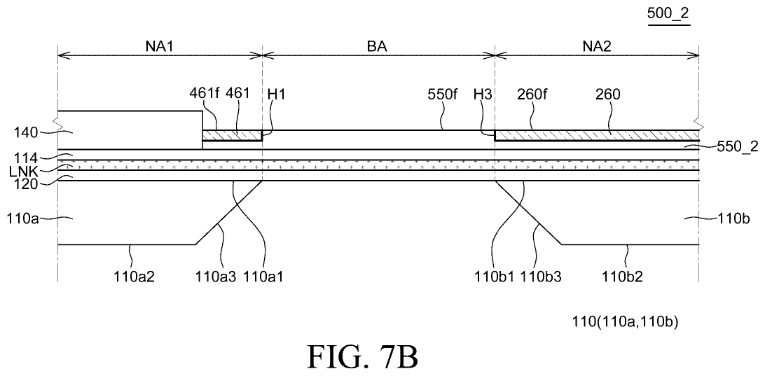

FIGS. 7A and 7B are plan views of a display device according to another exemplary embodiment of the present disclosure. In FIGS. 7A and 7B, for the convenience of illustration, only a first glass substrate 110a, a second glass substrate 110b, an etch stop layer 120, a link line LNK, a planarization layer 114, a polarizer 140, micro coating layers 550_1 and 550_2, rigid members 160 and 260, and an auxiliary rigid member 461 are schematically illustrated. A display device 500_1 illustrated in FIG. 7A is substantially the same as the display device 400_1 illustrated in FIG. 6A except for a micro coating layer 550_1 and a display device 500_2 illustrated in FIG. 7B is substantially the same as the display device 400_2 illustrated in FIG. 6B except for a micro coating layer 550_2. Therefore, a redundant description will be omitted or simplified.

Referring to FIG. 7A, the micro coating layer 550_1 includes a plurality of grooves H1 and H2 which is recessed from a top surface 550f so as to accommodate the rigid member 160 and the auxiliary rigid member 461. The plurality of grooves H1 and H2 may include a first groove H1 and a second groove H2.

The plurality of grooves H1 and H2 of the micro coating layer 550_1 may define a position in which the auxiliary rigid member 461 and the rigid member 160 are disposed. That is, the auxiliary rigid member 461 and the rigid member 160 may be disposed according to a position in which the plurality of grooves H1 and H2 of the micro coating layer 550_1 is formed. Specifically, the auxiliary rigid member 461 may be disposed in the first groove H1 and the rigid member 160 may be disposed in the second groove H2.

The first groove H1 of the micro coating layer 550_1 is formed adjacent to the bending area BA on the micro coating layer 550_1 so as to overlap the first glass substrate 110a in the first non-active area NA1. Specifically, the first groove H1 of the micro coating layer 550_1 may be formed so as to overlap an end of the top surface 110a1 and a side surface 110a3 of the first glass substrate 110a.

Further, an end of the first groove H1 adjacent to the bending area BA may be disposed to be in contact with the polarizer 140 and the other end of the first groove H1 may be disposed so as to match an end of the top surface 110a1 of the first glass substrate 110a.

The second groove H2 of the micro coating layer 550_1 is formed adjacent to the bending area BA so as to overlap at least a part of the second glass substrate 110b in the second non-active area NA2. Specifically, the second groove H2 of the micro coating layer 550_1 may be formed so as to overlap an end of the top surface 110b1 of the second glass substrate 110b and overlap a side surface 110b3 of the second glass substrate 110b.

Further, an end of the second groove H2 adjacent to the bending area BA is formed so as to match an end of the top surface 110b1 of the second glass substrate 110b and the other end of the second groove H2 may be disposed so as to match an end of the bottom surface 110b2 of the second glass substrate 110b.

The top surface 461f of the auxiliary rigid member 461 and the top surface 160f of the rigid member 160 may be the same plane as a top surface 550f of the micro coating layer 550_1 or protrude from the top surface 550f of the micro coating layer 550_1. That is, the top surface 461f of the auxiliary rigid member 461 and the top surface 160f of the rigid member 160 may be disposed to be lower than a top surface of the polarizer 140.

Accordingly, in a display device 500_1 according to another exemplary embodiment of the present disclosure, the auxiliary rigid member 461 and the rigid member 160 are disposed in the plurality of grooves H1 and H2 of the micro coating layer 550_1 overlapping the link line LNK. Therefore, the deformation of the micro coating layer 550_1 is reduced to reduce a stress of the link line LNK and minimize a tensile force to minimize generation of cracks.

Referring to FIG. 7B, the micro coating layer 550_2 includes a plurality of grooves H1 and H3 which is recessed from the top surface 550f so as to accommodate the rigid member 260 and the auxiliary rigid member 461. The plurality of grooves H1 and H3 may include a first groove H1 and a third groove H3.

The plurality of grooves H1 and H3 of the micro coating layer 550_2 may define a position in which the auxiliary rigid member 461 and the rigid member 260 are disposed. That is, the auxiliary rigid member 461 and the rigid member 260 may be disposed according to a position in which the plurality of grooves H1 and H3 of the micro coating layer 550_2 is formed. Specifically, the auxiliary rigid member 461 may be disposed in the first groove H1 and the rigid member 260 may be disposed in the third groove H3.

The first groove H1 of the micro coating layer 550_2 is formed adjacent to the bending area BA on the micro coating layer 550_2 so as to overlap the first glass substrate 110a in the first non-active area NA1. Specifically, the first groove H1 of the micro coating layer 550_2 may be formed so as to overlap an end of the top surface 110a1 and a side surface 110a3 of the first glass substrate 110a.

Further, an end of the first groove H1 adjacent to the bending area BA may be disposed to be in contact with the polarizer 140 and the other end of the first groove H1 may be disposed so as to match an end of the top surface 110a1 of the first glass substrate 110a.

The third groove H3 of the micro coating layer 550_2 is formed adjacent to the bending area BA so as to overlap the second glass substrate 110b in the second non-active area NA2. Specifically, one end of the third groove H3 of the micro coating layer 550_2 may be formed so as to match an end of the top surface 110b1 of the second glass substrate 110b and the other end of the third groove H3 of the micro coating layer 550_2 may be formed to an end of the micro coating layer 550_2 on the second glass substrate 110b. Therefore, the rigid member 260 is disposed in the third groove H3 and extends to an end of the micro coating layer 550_2 toward the pad unit PAD.

At this time, the top surface 461f of the auxiliary rigid member 461 and the top surface 260f of the rigid member 260 may be the same plane as a top surface 550f of the micro coating layer 550_2 or protrude from the top surface 550f of the micro coating layer 550_2. That is, the top surface 461f of the auxiliary rigid member 461 and the top surface 260f of the rigid member 260 may be disposed to be lower than a top surface of the polarizer 140.

Accordingly, in a display device 500_2 according to another exemplary embodiment of the present disclosure, the auxiliary rigid member 461 and the rigid member 260 are disposed in the plurality of grooves H1 and H3 of the micro coating layer 550_2 overlapping the link line LNK to extend to an end of the micro coating layer 550_2 toward the pad unit PAD. Therefore, the deformation of the micro coating layer 550_2 is reduced to reduce a stress of the link line LNK and minimize a tensile force to minimize generation of cracks.

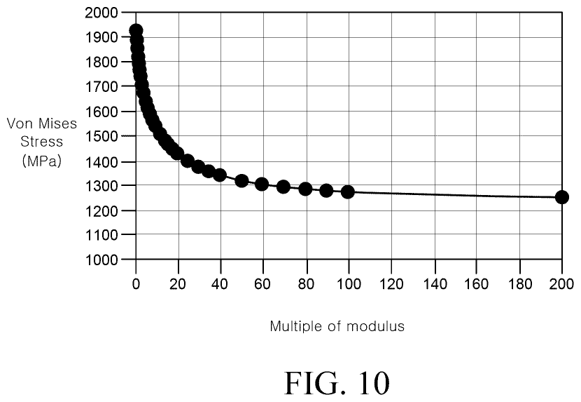

FIG. 10 is a graph obtained by analyzing a stress of a link line in a bending area according to a modulus of a rigid member according to an exemplary embodiment of the present disclosure by a finite element method. Here, an experimental condition for analyzing a stress of the link line of FIG. 10 is as represented in Table 1.

Referring to FIG. 10, an X-axis is a multiple of a modulus of the micro coating layer 150. For example, when a value of an X-axis is 10, it means a value obtained by multiplying 10 to a modulus of the micro coating layer. The Y-axis is a maximum von Mises stress of the link line LNK.

That is, through the graph, a change in the maximum von Mises stress of the link line LNK after being bent as the modulus of the rigid member 160 analyzed by the finite element method is increased to a multiple of a modulus of the micro coating layer 150 may be confirmed.

As the experiment result, the modulus of the rigid member 160 is gradually increased based on the modulus of the micro coating layer 150 so that it is understood that the von Mises stress of the link line LNK during the bending is gradually reduced. That is, it was understood that the von Mises stress of the link line LNK was reduced with a sharp slope from an initial value of approximately 1900 MPa or higher to approximately 1400 MPa at a point where the modulus of the rigid member 160 was 20 times a modulus of the micro coating layer 150.

Thereafter, in a section where the modulus of the rigid member 160 was 20 times to 80 times the modulus of the micro coating layer 150, the von Mises stress of the link line LNK was reduced with a gentle slope from approximately 1400 MPa to approximately 1300 MPa and the von Mises stress of the link line LNK was saturated at a point where the modulus of the rigid member 160 was more than 80 times a modulus of the micro coating layer 150, that is, in the section that the modulus of the rigid member 160 was 80 to 200 times a modulus of the micro coating layer 150.

As a result, the display device 100 according to the exemplary embodiment of the present disclosure includes a rigid member 160 having a modulus which is 20 times to 200 times the modulus of the micro coating layer 150. Therefore, the thickness of the micro coating layer 150 is changed in the corner portion S of the second glass substrate 110b during the bending to reduce a stress applied to the link line LNK.

Accordingly, the display device 100 according to the exemplary embodiment of the present disclosure reduces a deformation of the micro coating layer 150 to reduce a stress of the link line LNK and minimize a tensile force to minimize the generation of cracks. Further, the stress caused by the expansion and contraction generated in the high temperature and low temperature environment in the bending area BA is alleviated to improve the reliability of the display device 100.

The exemplary embodiments of the present disclosure can also be described as follows:

According to an aspect of the present disclosure, there is provided a display device. The display device includes an active area and a non-active area including a first non-active area adjacent to the active area, a bending area extending from the first non-active area, and a second non-active area extending from one side of the bending area. The display device comprises a first glass substrate disposed in the active area; a second glass substrate disposed in the second non-active area; an etch stop layer which is disposed so as to overlap the bending area; a link line disposed on the etch stop layer across the bending area; a micro coating layer which is disposed so as to overlap the first non-active area and at least a part of the second non-active area and is disposed on the link line in the bending area; and a rigid member which is disposed on the micro coating layer to be adjacent to the bending area so as to overlap at least a part of the second glass substrate.

The micro coating layer may include a groove recessed from a top surface so as to accommodate the rigid member and the rigid member is disposed in the groove.

A top surface of the rigid member may be coplanar with the top surface of the micro coating layer or protrudes from the top surface of the micro coating layer.

The display device may further comprise an auxiliary rigid member which is disposed on the micro coating layer to be adjacent to the bending area so as to overlap at least a part of the first glass substrate.

The rigid member may be disposed so as to overlap an end of a top surface of the second glass substrate.

Ends of top surfaces of the first glass substrate and the second glass substrate may be disposed to be adjacent to the bending area more than ends of bottom surfaces.

The first glass substrate and the second glass substrate may have side surfaces adjacent to the bending area which are inclined or recessed.

The rigid member may be disposed on the micro coating layer so as to overlap the side surface of the second glass substrate.

One end of the rigid member adjacent to the bending area may be disposed so as to match an end of the top surface of the second glass substrate.

The display device may further comprise a pad unit disposed in the second non-active area. The rigid member may extends toward the pad unit to an end of the micro coating layer.

A thickness of the rigid member may be 10% to 50% of a thickness of the micro coating layer.

A modulus of the micro coating layer may be 50 MPa to 200 MPa.

A modulus of the rigid member may be 20 times to 200 times the modulus of the micro coating layer.

The rigid member may include any one of polymer material, a metal material, and a ceramic material having a rigidity higher than that of the micro coating layer.

The etch stop layer may be disposed on the first glass substrate in the first non-active area and is disposed on the second glass substrate in the second non-active area and a bottom surface of the etch stop layer may be exposed between the first glass substrate and the second glass substrate in the bending area.

A thickness of the etch stop layer may be 1 μm to 5 μm.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure or claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device having an active area and a non-active area, wherein the non-active area includes a first non-active area adjacent to the active area, a bending area extending from the first non-active area, and a second non-active area extending from a side of the bending area, the display device comprising:
a first glass substrate disposed in the active area;
a second glass substrate disposed in the second non-active area;
an etch stop layer overlapping the bending area;
a link line disposed on the etch stop layer and extending across the bending area;
a micro coating layer overlapping the first non-active area and at least a part of the second non-active area, wherein the micro coating layer is disposed on the link line in the bending area; and
a rigid member disposed on the micro coating layer adjacent to the bending area, the rigid member overlapping at least a part of the second glass substrate.

2. The display device according to claim 1, wherein the micro coating layer includes a groove recessed from a top surface of the micro coating layer and the rigid member is disposed in the groove.

3. The display device according to claim 2, wherein a top surface of the rigid member is coplanar with the top surface of the micro coating layer or protrudes from the top surface of the micro coating layer.

4. The display device according to claim 1, further comprising:
an auxiliary rigid member disposed on the micro coating layer adjacent to the bending area, the auxiliary rigid member overlapping at least a part of the first glass substrate.

5. The display device according to claim 1, wherein the rigid member overlaps an end of a top surface of the second glass substrate.

6. The display device according to claim 1, wherein an end of a top surface of the first glass substrate and an end of a top surface of the second glass substrate are each disposed closer to the bending area than an end of a bottom surface of the first glass substrate and an end of a bottom surface of the second glass substrate.

7. The display device according to claim 6, wherein the first glass substrate and the second glass substrate have inclined or recessed side surfaces adjacent to the bending area.

8. The display device according to claim 7, wherein the rigid member overlaps the inlined or recessed side surface of the second glass substrate.

9. The display device according to claim 7, wherein an end of the rigid member adjacent to the bending area is aligned with an end of the top surface of the second glass substrate.

10. The display device according to claim 1, further comprising:
a pad disposed in the second non-active area,
wherein the rigid member extends toward the pad to an end of the micro coating layer.

11. The display device according to claim 1, wherein a thickness of the rigid member is 10% to 50% of a thickness of the micro coating layer.

12. The display device according to claim 1, wherein a modulus of elasticity of the micro coating layer is 50 MPa to 200 MPa.

13. The display device according to claim 12, wherein a modulus of elasticity of the rigid member is 20 times to 200 times the modulus of elasticity of the micro coating layer.

14. The display device according to claim 1, wherein the rigid member includes any one of a polymer material, a metal material, and a ceramic material and the rigid member has a rigidity that is greater than a rigidity of the micro coating layer.

15. The display device according to claim 1, wherein the etch stop layer is disposed on the first glass substrate in the first non-active area and is disposed on the second glass substrate in the second non-active area, and
wherein a bottom surface of the etch stop layer is exposed between the first glass substrate and the second glass substrate in the bending area.

16. The display device according to claim 1, wherein a thickness of the etch stop layer is 1 μm to 5 μm.
